(19) United States
(12) Patent Application Publication
(10) Pub. No.: US 2012/0153785 A1
(43) Pub. Date: Jun. 21, 2012

(54) PACKAGE STRUCTURE

(76) Inventors: Chen-Ju LAI, Taipei (TW); Po-Jen Huang, Taipei (TW); Kuan-Chen Fang, Taipei (TW); Chiao-Hui Chang, Taipei (TW)

(21) Appl. No.: 13/314,784

(22) Filed: Dec. 8, 2011

Related U.S. Application Data
(60) Provisional application No. 61/424,438, filed on Dec. 17, 2010.

(51) Int. Cl. H05K 5/02

(52) U.S. Cl. 312/223.2; 312/223.1

(57) ABSTRACT

A package structure for an electronic component is disclosed. The package structure includes a box body and a first cutting line. The first cutting line is formed at the box body and defines a first plate. The first plate can be detached from the box body along the first cutting line and forms a connecting hole for the electronic component. The package structure is used as an environmental friendly computer assembly casing and solves the problem of buying an additional computer assembly casing.

### CROSS REFERENCE TO RELATED APPLICATIONS

The non-provisional patent application claims priority to U.S. provisional patent application with Ser. No. 61/424,438 filed on Dec. 17, 2010. This and all other extrinsic materials discussed herein are incorporated by reference in their entirety.

### BACKGROUND OF THE INVENTION

1. Field of Invention

The invention relates to a package structure and, more particularly, to an assembly casing for an electronic device.

2. Related Art

To protect products such as precise electronic devices, well packing is very important. However, most packing boxes have no other usage after purchasing by costumers, therefore, lots of waste produced. Reducing total waste is now a main issue worldwide, nowadays, unnecessary packing, using simple and lighten packages instead of complicated packing for products are undertaking. Furthermore, expanding the package for more function can also reduce the total waste.

Packing boxes with brand or advertisement printed in color are conventional package structures for electronic components or even devices. Taking a motherboard package as an example, the box is not only for highlighting a brand and advertising, but also for protecting motherboard products and to absorb or dissipate energy as shock absorber while transportation and storage. However, after users open the box and take out the motherboard, the packing box is useless. Thought packing boxes often made by paper and can be recycled and reduced the environmental pollution. However, since the packing boxes are large in size and difficult to be folded, it is not easy for recycling.

Further, after the electronic component, such as the motherboard, is taken out of the packing box, it is easy to accumulate dust or damaged by accident. Thus, users have to buy an outer assembly casing for assembly, which is rather inconvenient. Moreover, if the size or the outlook configuration of the motherboard is special, it is difficult to get an appropriate assembly casing, which is troublesome and wasteful.

### SUMMARY OF THE INVENTION

A package structure of an electronic component is disclosed. The package structure has features of a package and an assembly casing for assembly electronic components. When the electronic component is wrapped, the package structure can absorb or dissipate energy and protect the electronic component therein. With simple steps, the package structure can be a temporary assembly casing for the electronic component assembly casing after the component is taken out from the package structure. As a result, users do not need to buy an additional assembly casing for assembly, the components can be protected in the temporary assembly casing of the package structure in a convenient way.

The package structure for packing an electronic component is disclosed. The package structure includes a box body and a first cutting line. The first cutting line is formed at the box body, and the first cutting line defines a first plate in any shape. The first plate can be detached from the box body along the first cutting line to form a connecting hole for the electronic component.

In conventional technology, though the packing box made of paper can be recycled to reduce environmental pollution, however, it still becomes useless after it is un-wrapped. The package structure in an embodiment disclosed herein can be re-formed as an assembly casing. By adding some fixing part in the assembly casing and connecting cables for full usage of the package, and the user does not need to buy an assembly casing additionally.

These and other features, aspects and advantages of the present invention will become better understood with regard to the following description, appended claims, and accompanying drawings.

### BRIEF DESCRIPTION OF THE DRAWINGS

FIG. 1A is a schematic diagram showing a package structure in a first embodiment;

FIG. 1B is a perspective diagram showing the package structure in FIG. 1A;

FIG. 1C is a schematic diagram showing that a first plate of the package structure in FIG. 1A is detached from a box body along a first cutting line and a connecting hole is formed;

FIG. 2 is a schematic diagram showing a package structure in a second embodiment;

FIG. 3A is a schematic diagram showing that a first fixing part, a second fixing part and an electronic component are taken out from a package structure in a third embodiment; and

FIG. 3B is a schematic diagram showing that the package structure in FIG. 3A is combined with the electronic component.

### DETAILED DESCRIPTION OF THE INVENTION

A package structure is illustrated with relating figures below, and the same symbols denote the same components.

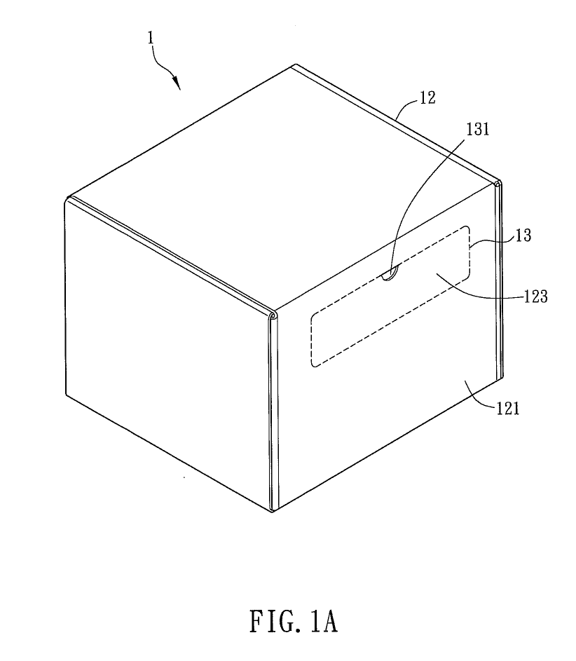

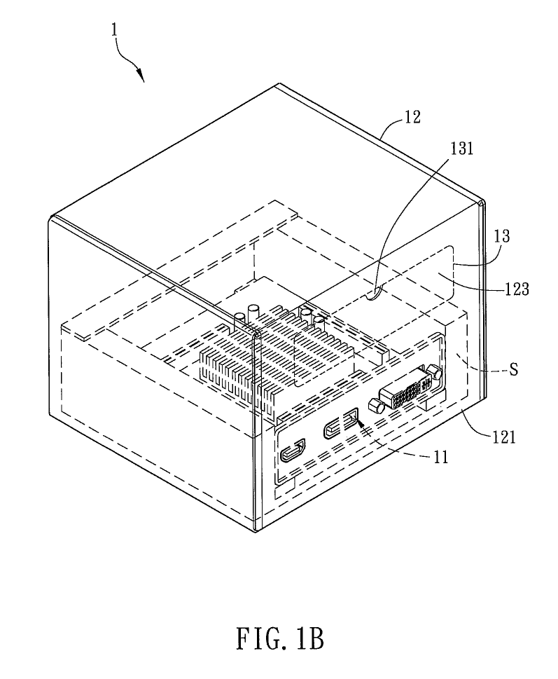

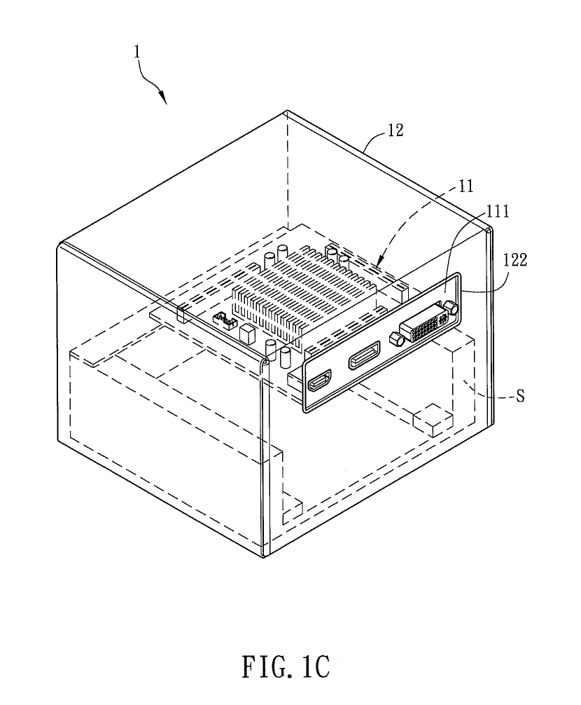

FIG. 1A is a schematic diagram showing a package structure in a first embodiment, and FIG. 1B is a perspective diagram showing the package structure in FIG. 1A. The package structure 1 is used to wrap an electronic component 11. In the embodiment, the electronic component 11 is a motherboard for an example, which is not limited herein. The electronic component 11 may also be a hard disk, an optical disk drive (ODD) or other electronic devices of a computer. The package structure 1 includes a box body 12 and a first cutting line 13. The package structure 1 may be made of cardboard, fluting paper, plastic board, Polyron board or composite board. It is to be understood that the materials for the package structure 1 can be chosen according to packing requirements and environmental concerns, which is not limited herein.

In an embodiment, the package structure 1 also includes a buffer part S. the buffer part S is accommodated in the box body 12 to fix the electronic component 11 and prevent the electronic component 11 from shaking or swaying while transportation. The material of the buffer part S may be the same as that of the package structure 1 without limited herein. The buffer part S may be integratedly formed in the box body 12, or it is formed separately and put in the box body 12, which is not limited herein.

The box body 12 can be opened by turning an opening part 121 upward or turning two boards of the box body 12 at opposite directions, which is not limited herein. The opening mode is known by persons having ordinary skill in the art, which is omitted herein.

The first cutting line 13 may be formed at any side of the box body 12 and, more particularly, the first cutting line 13 is formed at one side of the box body 12 based on the usage of the electronic component 11. Taking the motherboard as an example, the first cutting line 13 is formed at front side or back side of the box body 12 corresponding to the electronic component 11, and the first cutting line 13 defines a first plate 123 in any shape. In FIG. 1A, the first plate 123 is rectangular-shaped and includes a concave hole 131. The concave hole 131 can be torn to detach the first plate 123 from the box body 12 along the first cutting line 13. The first cutting line 13 may be formed at the box body 12 in various ways for users can easily separate the first plate 123 from the box body 12 along the first cutting line 13. The first cutting line 13 may be a tooth shape line or a cutting line, which is not limited herein.

FIG. 1C is a schematic diagram showing that the first plate of the package structure showed in FIG. 1A is separated. After the first plate 123 is separated from the box body 12 along the first cutting line 13, a connecting hole 122 for electrical connecting with the electronic component 11 is formed. In some embodiments, the position of the electronic component 11 in the box body 12 can be adjusted to fit the connecting hole 122 on the box body 12 for better performance. In other words, a hard disk or an ODD (not shown) may be put under the electronic component 11 to make the position of the connecting module 111 correspond to that of the connecting hole 122 to expose the connecting module 111 from the box body 12. Specifically, in some embodiments, the first plate 123 is only partially detached from the box body 12 instead of whole plate, and one side of the first plate 123 may remain connected with the box body 12. Thus, the first plate 123 can be opened and closed freely at the box body 12.

The connecting module 111 may be an interface with a basic input/output port, a universal serial bus (USB) port or a power receptacle, which is not limited herein. Thus, main part of the electronic component 11 is put and protected inside the box body 12, and the connecting module 111 is exposed for connection. Consequently, the package structure 1 can be used as a computer assembly casing.

For more detail, the number of the first cutting line 13 of the package structure 1 is not limited, and each of the connecting holes 122 is also not limited whether it is to be formed by a single first cutting line 13 or multiple cutting lines. In other words, the package structure 1 may include a plurality of first cutting lines 13 and form multiple connecting holes 122, or each of the connecting holes 122 is formed by multiple first cutting lines 13, which is not limited herein.

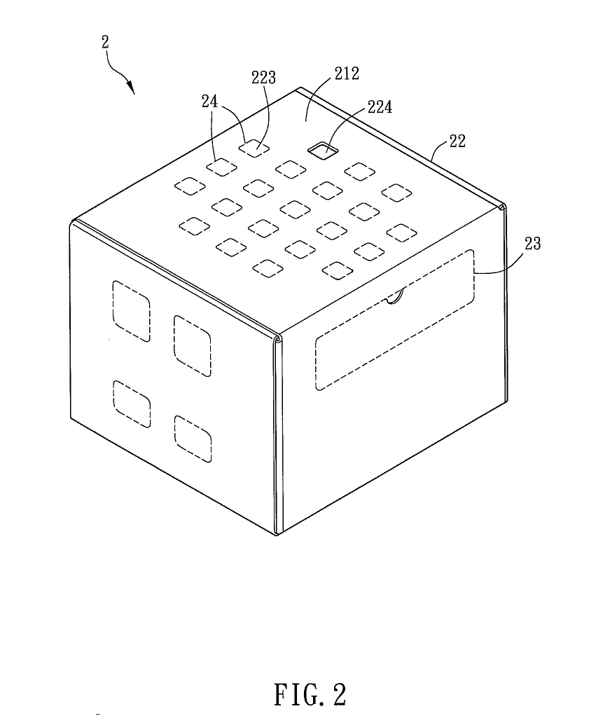

The package structure may further include a second cutting line formed at the box body, and the second cutting line defines a second plate in any shape. The second plate is detached from the box body along the second cutting line to form a heat dissipating hole. FIG. 2 is a schematic diagram showing a package structure in a second embodiment. The package structure 2 may include multiple second cutting lines 24 that formed at a heat dissipating side 212 of the box body 22 corresponding to the electronic component 21. When the user takes the second plate 223 off from the box body along the second cutting line 24, air flows through the heat dissipating hole 224 for heat dissipating. Similarly, the second cutting line 24 may be formed in various ways, and the number of the second cutting line 24 and the shape for defined the heat dissipating hole 224 are not limited, and can be adjusted according to different requirements. For example, the heat dissipating hole 224 may be a single big circular hole to meet requirements of a fan. Moreover, the first cutting line 23 and the second cutting line 24 can also be the same and have the same configuration to form the same connecting holes 222 and 224.

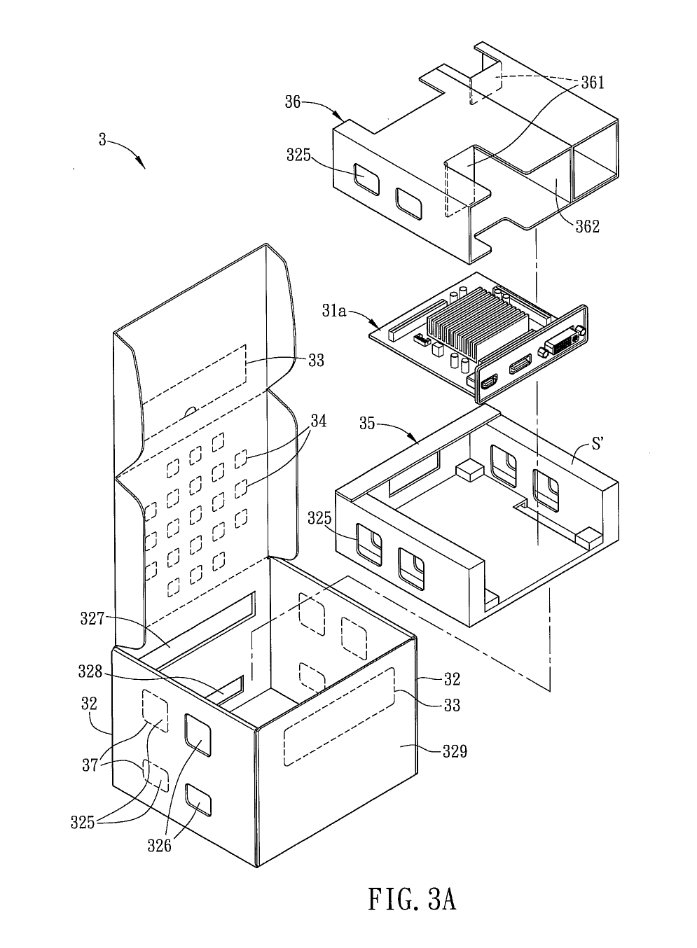

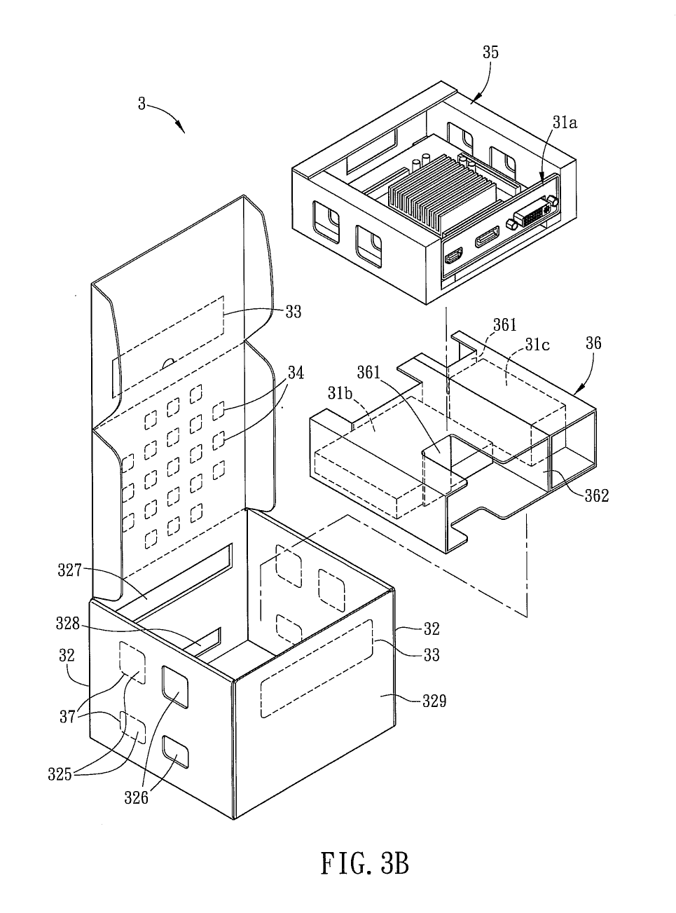

FIG. 3A is a schematic diagram showing that a first fixing part, a second fixing part and an electronic component are taken out from a package structure in a third embodiment, and FIG. 3B is a schematic diagram showing that the package structure in FIG. 3A is combined with the electronic component. Components structure and features of the package structure 3 are similar with those of the package structure in the second embodiment, which is omitted herein. In the embodiment, the package structure 3 includes a first fixing part 35, a second fixing part 36 and a third cutting line 37. The first fixing part 35 and the second fixing part 36 are accommodated in the box body 32. In an embodiment, the size and structure of the first fixing part 35 and the second fixing part 36 can be correspond to different electronic components, respectively, and the total volume of the first fixing part 35 and the second fixing part 36 is almost equal to that of the box body 32. Thus, after the assembly is finished, each of the electronic components can be held at fixed positions. Taking the motherboard as an example, the first fixing part 35 includes a buffer part S′, and thus when the electronic component 31a is fixed in the first fixing part 35, it would not be shaken or swayed.

In an embodiment, the second fixing part 36 is used for fixing the ODD and the hard disk when they are connected with the motherboard. Further, a plurality of abutting parts 361 and a division part 362 can be included for more steady. The division part 362 divides inner space of the second fixing part 36 into two parts for the hard disk and the ODD. In an embodiment, the size of the hard disk may be 2.5 inches, and the ODD may be a thin-type ODD which are not limited herein. The abutting parts 361 support the electronic component, such as the hard disk or the ODD, to prevent the electronic component from swaying or moving.

Multiple third cutting lines 37 may be formed at the box body 32, and the third cutting line 37 may define a third plate 325 in any shape. The third plate 325 is detached from the box body 32 along the third cutting line 37 to form a component connecting hole 326. The component connecting hole 326 is used for the motherboard connecting with the electronic component such as the hard disk or the ODD. Taking environmental protection and cost into consideration, the size of the box body 32 can be little larger than that of the first fixing part 35 and the second fixing part 36. Lines for connecting the components can pass the box body 32 through a component connecting hole 326, and then enter the box body 32 through another component connecting hole 326, so as to simplify lines connection and decrease heat dissipating problem. Position to form the third cutting line 37 is not limited, however, in an embodiment, the third plate 325 defined by the third cutting line 37 can be formed on the first fixing part 35 and the second fixing part 36, and the connecting lines can pass through the component connecting hole 326 that formed by taking off the third plate 325.

The cutting line may be formed at different positions at the box body 32 to improve the functionality of the package structure 3 as a computer assembly casing. For example, a fourth cutting line can define a fourth plate (not shown) in any shape. The fourth plate can be taken off from the box body 32 along the fourth cutting line to form an operation interface hole 327 for the power controlling or USB connecting. Furthermore, in another embodiment, other cutting lines also can be formed at the same side having operation interface hole 327, and the position of the cutting line corresponds to the electronic component with media read or write functions, such as the ODD, to form a media gateway 328. In an embodiment, the box body 32 further includes a front plate 329, for strengthens the whole structure of the box body 32. Further, the first cutting line 33 can be formed thereon to form an inner connecting hole.

As shown in FIG. 3B, while transportation or storage, the first fixing part 35 and the electronic component 31a are stored under the second fixing part 36. After the assembly of the electronic components 31a, 31b, 31c, the second fixing part 36 is re-located under the first fixing part 35 and the electronic component 31a to improve heat dissipating efficiency and facilitations to the user. It is to be understood that the assembly positions of the first fixing part 35 and the second fixing part 36 are various, which is not limited herein. The plates detached or un-completely detached from the box body 32 along the cutting lines can be recombined with the box body 32, and thus the package structure can be restored to its original shape while another transportation so as to further decrease wastes.

In sum, according to the description about the package structure for an electronic component, the first cutting line is formed at the box body, and the first plate defined by the first cutting line is detached from the box body to form the connecting hole for the electronic component. Thus, when the electronic component is disposed in the package structure, it can be connected to other components or devices via the connecting hole of the box body. Consequently, the package structure will have further functions even when the component is un-wrapped. The package structure may be used as a computer assembly casing for the electronic component which have to connecting holes for the motherboard to be connected with other devices. For example, the motherboard in the package structure does not need to be disposed to an additional assembly casing after it is taken out. Further, the connecting lines, such as an input/output line or a power line, can be connected to the motherboard in the box body via the connecting hole, and the box body can also protect the motherboard and prevent the motherboard from dust accumulate. Thus, the user does not need to buy an assembly casing additionally or look for an appropriate assembly casing for the motherboard with a special size.

Although the present invention has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. A package structure for an electronic component, the package structure comprising:
a box body; and
a first cutting line formed at the box body and defining a first plate, wherein the first plate is detached from the box body along the first cutting line and forms a connecting hole at the box body for the electronic component.

2. The package structure according to claim 1, wherein the package structure further includes:
a second cutting line defining a second plate, wherein the second plate is detached from the box body along the second cutting line to form a heat dissipating hole at the box body.

3. The package structure according to claim 1, wherein the package structure further includes:
a first fixing part accommodated in the box body.

4. The package structure according to claim 3, wherein the electronic component is disposed in the first fixing part.

5. The package structure according to claim 3, wherein the first fixing part includes a plurality of abutting parts.

6. The package structure according to claim 3, wherein the package structure further includes:
a second fixing part accommodated in the box body.

7. The package structure according to claim 6, wherein the second fixing part includes a plurality of abutting parts.

8. The package structure according to claim 6, wherein the second fixing part includes a division part.

9. The package structure according to claim 1, wherein the package structure further includes:
a buffer part accommodated in the box body to fix the electronic component.

10. The package structure according to claim 1, wherein the electronic component is a motherboard, an access device or an optical disk drive (ODD).
